(19) United States
(12) Patent Application Publication
(10) Pub. No.: US 2026/0225451 A1
(43) Pub. Date: Aug. 6, 2026

(54) CONTROL DEVICE FOR ACTIVATING AND DEACTIVATING A Y-CAPACITOR, INVERTER AND ELECTRIC DRIVE SYSTEM

(71) Applicant: Robert Bosch GmbH, Stuttgart (DE)

(72) Inventor: Edwin Eberlein, Stuttgart (DE)

(21) Appl. No.: 19/150,222

(22) PCT Filed: Oct. 17, 2023
(86) PCT No.: PCT/EP2023/078826

§ 371 Date: Jul. 23, 2025

(30) Foreign Application Priority Data
Jan. 24, 2023 (DE) 10 2023 200 512.3

(51) Int. Cl. B60L 3/00; B60L 50/51; G01R 31/27; H03K 17/18

(52) U.S. Cl. CPC B60L 3/003; B60L 50/51; G01R 31/27; H03K 17/18; B60L 2210/42

(57) ABSTRACT

The invention relates to a circuit arrangement that makes it possible to activate or deactivate a Y-capacitor in a galvanically isolated manner and at the same time to test a switching state of the switching element for activating or deactivating the Y-capacitor.

### BACKGROUND

The present invention relates to a control device for activating and deactivating a Y-capacitor, as well as an inverter and an electric drive system having such a control device.

Although the present invention will be described below in connection with an electric drive system for an electric vehicle, the invention is not limited to this. Rather, the present invention can in principle also be applied to any other systems in which Y-capacitors are to be activated or deactivated in a targeted manner.

Electric drive systems typically include an inverter that converts an electrical voltage supplied on the input side to a further voltage suitable for driving an electrical machine. In this case, so-called Y-capacitors can be provided on the input terminals of such an inverter, wherein a Y-capacitor is arranged between an input terminal and a ground.

Publication DE 10 2020 121 248 A1 discloses a circuit arrangement for charging an electric vehicle with switchable Y-capacitors between phase connectors and a neutral conductor, wherein the Y-capacitors can be deactivated in an idle state of the circuit arrangement.

### SUMMARY

The present invention discloses a controller for activating and deactivating a Y-capacitor, as well as an inverter and an electric drive system having the features of the disclosure.

The following is provided:
A controller for activating and deactivating a Y-capacitor, wherein the Y-capacitor is arranged between a power supply line and a node point, and a semiconductor switching element for activating and deactivating the Y-capacitor is arranged between the node and a ground. The controller comprises a transformer, a first control device, a second control device and a diode. The transformer includes a primary side and a secondary side. The first control device is designed to provide predetermined control pulses to the primary side of the transformer. The control pulses are designed to signal a desired switching state of the semiconductor switching element. The secondary side of the transformer T is electrically coupled to the second control device. Furthermore, the second control device is designed to control the semiconductor switching element using the voltage signals present at the secondary terminal of the transformer. The diode is located between a first terminal of the secondary side of the transformer and the node. The second terminal of the secondary side of the transformer may be connected to a ground.

The following is furthermore provided:
An electrical inverter having an input terminal and an inverter circuit. The input terminal is designed to be connected to a DC electric voltage source at a first connection point and a second connection point. The inverter circuit is designed to convert a DC electric voltage supplied at the input terminal into an AC voltage and to supply it to an output terminal. Furthermore, a series circuit consisting of a Y-capacitor and a semiconductor switching element is arranged between a ground and the first connection point and between the ground and the second connection point. In addition, a controller according to the invention is provided for each Y-capacitor.

Finally, the following is provided:
An electric drive system, in particular an electric drive system for an electric vehicle with an electric machine, and an electrical inverter according to the invention.

As Y-capacitor capacitance increases, so does the electrical energy stored in these capacitors. Particularly for electric drive systems powered by a high-voltage DC voltage source, it is necessary to be able to discharge these capacitors as quickly as possible when the drive system is turned off.

It is therefore an idea of the present invention to activate Y-capacitors only when they are actually needed. It is desirable to reliably verify the respective switching state, i.e. the activation or deactivation of the Y-capacitors.

In light of this, the present invention creates a controller for activating or deactivating Y-capacitors, which can easily verify the respective state of the Y-capacitors. It is thus possible on the one hand to provide the capacitances of the Y-capacitors as needed, in order to minimize high-frequency interference, for example. On the other hand, the capacitances of the Y-capacitors may be deactivated or switched off when not needed. Thus, no electrical energy is stored in the deactivated Y-capacitors, which may represent a hazard to people.

In addition, due to the possibility of verifying the current state, i.e. activation or deactivation of the Y-capacitors, it is also ensured that the desired configuration is present. As a result, it can be ensured on the one hand that the Y-capacitors can also guarantee the required filtering of high-frequency interference, if necessary, and on the other hand, it can be ensured that the Y-capacitors are also reliably decoupled when they are not needed.

Thus, by means of the diode between a terminal on the secondary side of the transformer and the node at which the Y-capacitor is connected to the semiconductor switching element for activating/deactivating the Y-capacitor, a current feedback to the primary side of the transformer can be achieved, which allows conclusions to be drawn about the switching state of the semiconductor switching element on the primary side of the transformer. Thus, on the primary side of the transformer, a galvanically isolated check of the switching state of the semiconductor switching element can be realized and thereby the function of the Y-capacitor can be analyzed.

According to one embodiment, the first control device is designed to sense an electrical current on the primary side of the transformer and determine a switching state of the semiconductor switching element using the sensed electrical current. In particular, the control device may evaluate the electrical current with the control pulses when applied to the primary side of the transformer. As already stated above, the diode according to the invention between the secondary side of the transformer and the node at which the Y-capacitor and semiconductor switching element are connected together can achieve a current retroactive effect on the primary side of the transformer, which allows conclusions to be made about the switching state of the semiconductor switching element.

According to one embodiment, the first control device is designed to detect a malfunction of the semiconductor switching element if the determined switching state of the semiconductor switching element deviates from the switching state signaled by the control pulses. In other words, if there is a discrepancy between the integrated result of the switching state of the semiconductor switching element and the requested switching state, this indicates a malfunction. This may be indicated by corresponding signaling, for example analog or digital output signals. If necessary, further measures may be initiated, for example, a shutdown of the system, continued operation with reduced power or in an emergency operation mode, or the like. Furthermore, such an error may optionally also be stored in an error memory and may be read out at a later date, for example in a workshop.

According to one embodiment, the control pulses each comprise a first time period and a second time period. In this case, the control pulses each have a predetermined first voltage level in the first time period. Furthermore, during the second time period, the control pulses have a voltage curve that respectively signals the desired switching state of the semiconductor switching element. The maximum voltage level may be less during the second time period than the voltage level during the first time period. For example, during the second time period, a state in which the semiconductor switching element is to be closed to activate the Y-capacitor can be signaled by a longer pulse at a predetermined voltage level. Furthermore, a shorter pulse within the second time period may request a switching state at which the semiconductor switching element is to be opened to deactivate the Y-capacitor.

In accordance with one embodiment, the controller is designed to close the semiconductor switching element in the series circuit consisting of the Y-capacitor and semiconductor switching element in a first operating mode. Accordingly, in a second operating mode, the semiconductor switching elements in the series circuit consisting of the Y-capacitor and semiconductor switching element can be opened. For example, the first operating mode may be set with the Y-capacitor activated when a further component, such as an electric inverter, connected to the Y-capacitor is active. If this connected component is not active, however, the Y-capacitor can also be deactivated. In particular, for example, in an electric vehicle, the first operating mode may be set with the Y-capacitor activated when the vehicle is in a driving mode in which the electric drive system of the vehicle is active. If the vehicle is stopped or, for example, is currently being charged, the Y-capacitors may be deactivated at the input of an electric inverter of the drive system.

The above embodiments and further developments can be combined with one another in any desired manner insofar as advantageous. Additional embodiments, further developments, and implementations of the invention also include inventive feature combinations not described or explicitly specified hereinabove or hereinafter with respect to exemplary embodiments. The skilled person will in particular also add individual aspects as improvements or additions to the respective basic forms of the invention.

### BRIEF DESCRIPTION OF THE DRAWINGS

Further features and advantages of the invention are explained hereinafter with reference to the drawings. Shown are:

FIG. 1: a schematic representation of an electric drive system with a controller according to one embodiment;

FIG. 2: a schematic diagram of a controller according to one embodiment;

FIG. 3: a voltage timing diagram for illustrating control pulses as may be provided in a controller according to one embodiment; and

FIG. 4: a voltage timing diagram for illustrating further control pulses as may be provided in a controller according to one embodiment.

### DETAILED DESCRIPTION

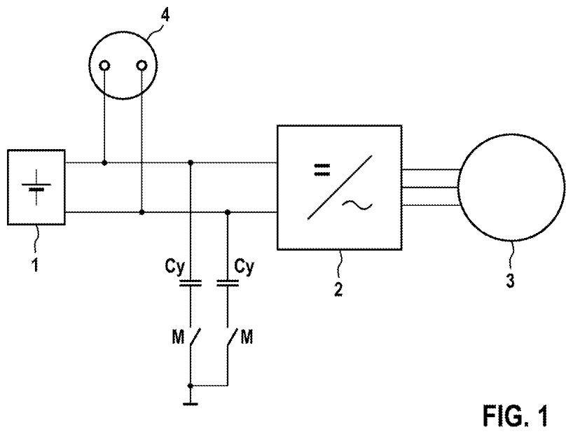

FIG. 1 shows a schematic diagram of an electric drive system according to one embodiment. The electric drive system comprises an electric inverter 2 and an electric machine 3. The electric inverter 2 can be supplied on the input side at a DC voltage connection from a DC voltage source 1, for example a traction battery of an electric vehicle with a DC voltage. For example, the inverter 2 may convert this DC voltage into a single-phase or multi-phase AC voltage according to target values and provide this AC voltage to the electric machine 3. Optionally, the inverter 2, in a recovery mode, can also convert electric AC voltage supplied by the electric machine 3 in a generator mode into a DC voltage that is suitable for charging a battery connected to the DC voltage terminal.

A charging circuit 4 may also be provided, if necessary. By means of this charging circuit 4, the DC voltage source 1, in particular the traction battery, can be charged by an external power source. The switching elements provided for this purpose for disconnecting the connections between charging circuit 4, DC voltage source 1 and inverter 2 are not shown in FIG. 1 for ease of viewing.

The so-called Y-capacitors Cy can be provided at the DC voltage connection of the inverter 2. In this case, a Y-capacitor Cy can be provided between the two DC voltage lines at the DC voltage terminal of the inverter 2 and a ground. Furthermore, a switching element, in particular a semiconductor switching element M, can be provided between each Y-capacitor Cy and the ground. Thus, by closing this semiconductor switching element M, the respective Y-capacitor Cy can be activated. Accordingly, by opening the semiconductor switching element M, the respective Y-capacitor Cy can be deactivated.

For example, the Y-capacitors Cy may be activated by closing the semiconductor switching elements M when the inverter 2 is active, particularly when the electric drive system is in an active state. For example, if the electric drive system is the propulsion system of an electric vehicle, then the Y-capacitors Cy may be activated by closing the semiconductor switching elements M when the vehicle is in a travel mode. If the vehicle is turned off and, for example, charged, then the Y-capacitors Cy may be deactivated by opening the semiconductor switching elements M. In principle, it is also possible to provide a further, preferably smaller capacitance in parallel to the series circuits consisting of a Y-capacitor Cy and the corresponding switching element M, in addition to the activatable/deactivatable Y-capacitors Cy. Thus, by activating the Y-capacitors and the resulting parallel circuit with the further capacitor, a large total capacitance can be achieved, while only the small capacitance of the further capacitor remains effective when deactivating the Y-capacitor.

Control of the semiconductor circuit elements M for opening or closing can be carried out, for example, by means of the controller 100, which is explained in more detail below.

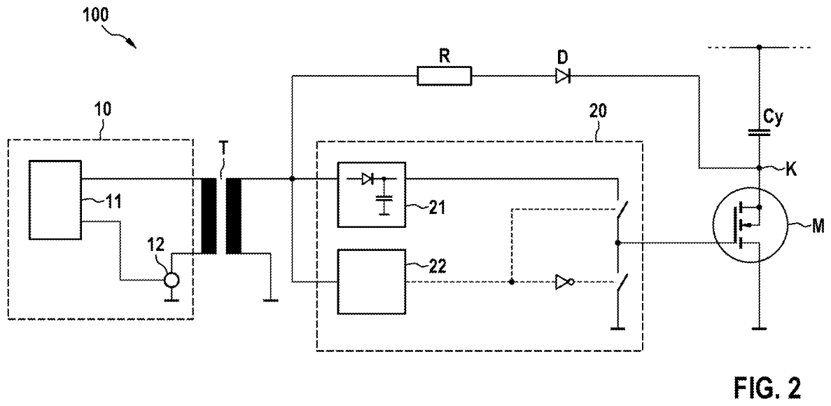

FIG. 2 shows a schematic diagram of a controller 100 for activating and deactivating Y-capacitors Cy, according to one embodiment. The controller 100 comprises a first control device 10, a second control device 20, a transformer T and a diode D.

The first control device 10 comprises a control element 11, which generates control pulses explained in more detail below, and provides them on the primary side of the transformer T.

The secondary side of the transformer T is connected to the second control device 20. In particular, the second control device 20 may comprise a power supply component 21 and a control component 22. The power supply component 21 may generate an electrical voltage from the electrical voltage supplied to the secondary side of the transformer T, which is suitable for supplying electrical power to the control component 22. For example, in the power supply component 21, the electrical voltage supplied at the secondary side of the transformer T can be rectified and stored in a capacitor.

The control component 22 evaluates the voltage signal provided on the secondary side of the transformer T. In particular, the control component 22 may open or close the semiconductor circuit element M, depending on the signal curve of the voltage signal on the secondary side of transformer T. For this purpose, a corresponding control signal can be provided from the control component 22 on the control terminal of the semiconductor switching element.

Furthermore, a diode D is provided between the node point K, at which the Y-capacitor Cy is connected to the semiconductor switching element M, and a first connection point of the secondary side of the transformer T.

In particular, an electrical resistance R can also be provided in series with this diode D. By means of this electrical resistance R, for example, the electrical current in this current path can be limited or adjusted. For example, the second connection point on the secondary side of the transformer may be connected to a ground.

An electrical current can thus flow through the current path with diode D between the first connection point on the secondary side of the transformer T and the node K when the semiconductor switching element M is closed. This electrical current causes a retroactive effect on the primary side of the transformer T.

A current sensor 12 is provided in the first control device 10, which can detect the electrical current on the secondary side of the transformer T. The current sensor 12 may provide its sensor signal to the control element 11. Thus, the control element 11 may evaluate this sensor value from current sensor 12 and determine the switching state of semiconductor switching element M. Furthermore, control element 11 may compare the determined switching state of semiconductor switching element M with the requested switching state. If there is a discrepancy between the determined switching state and the requested switching state, a malfunction can be detected. A corresponding error message can then be signaled. For example, in such a case, the functionality of the system with Y-capacitors Cy may be limited or fully deactivated.

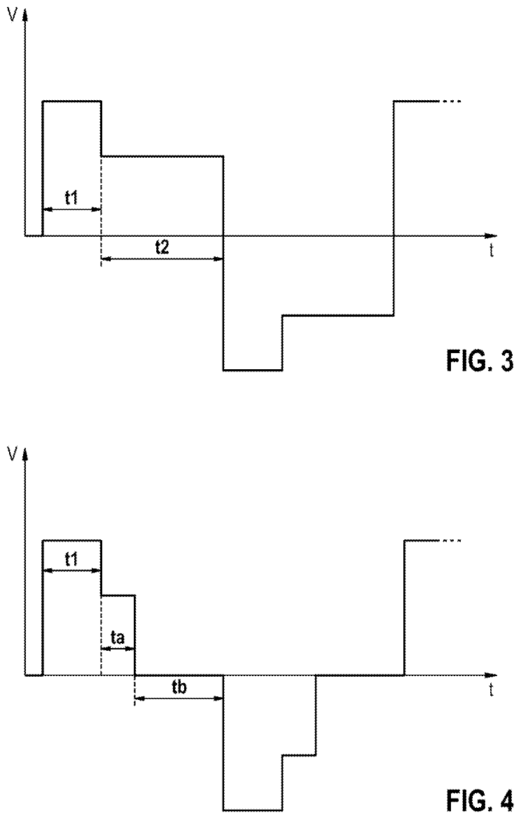

FIGS. 3 and 4 show voltage/time diagrams of the control pulses as can be provided by the first control device 10, for example on the primary side of the transformer T. FIG. 3 illustrates an exemplary curve of the voltage pulses for closing the semiconductor switching element M, and FIG. 4 illustrates an exemplary curve of the voltage pulses for opening the semiconductor switching element M.

As can be seen in FIG. 3, the control pulses may be divided into two time periods t1 and t2. In the first time period t1, the control pulse may take on a predetermined first voltage value. This can, for example, ensure that a sufficient amount of electrical energy is transmitted from the primary side to the secondary side of the transformer T by means of the control pulses in order to supply electrical energy to the second control device 20. During the subsequent second time period t2, signaling about the desired switching state of the semiconductor switching element can take place. For example, to close the semiconductor switching element M, a voltage pulse can be output with a second voltage value over the entire duration of the second time period t2. This second voltage value may be less than the first voltage during the first time period t1.

After outputting the voltage curve with positive voltages described above, a voltage curve with negative voltages of the same magnitude can then be output. This may be repeated periodically as long as the desired switching state for the semiconductor switching elements M is to be maintained.

FIG. 4 illustrates a possible voltage curve for opening the semiconductor switching element M. The first time section t1 with the voltage pulse of the first voltage value is identical to the voltage pulse for closing the semiconductor switching element M described above. However, during the subsequent second time section t2, there is only a short time period ta with the second voltage value to signal the opening of the semiconductor switching element M. A subsequent time period tb has a voltage of approximately 0 Volts. Also, the described voltage curve can be output alternately with positive and negative voltages.

In this way, it is possible on the one hand to supply electrical power to the second control device 20 on the secondary side of the transformer T by means of the output voltage pulses and thereby additionally signal the desired switching state for the semiconductor switching element M.

Due to the feedback of the electrical current through the current path with the diode D, a conclusion about the switching state of the semiconductor switching element M can be made by means of a current measurement on the primary side of the transformer T.

In summary, the invention relates to a circuit arrangement that makes it possible to activate or deactivate a Y-capacitor in a galvanically isolated manner and at the same time to test a switching state of the switching element for activating or deactivating the Y-capacitor.

1. A controller (100) for activating and deactivating a Y-capacitor (Cy), wherein the Y-capacitor (Cy) is arranged between a power supply line and a node point (K), and a semiconductor switching element (M) for activating and deactivating the Y-capacitor (Cy) is arranged between the node point (K) and a ground, with:
a transformer (T) having a primary side and a secondary side;
a first control device (10) configured to provide predetermined control pulses to the primary side of the transformer (T), wherein the control pulses are configured to signal a desired switching state of the semiconductor switching element (M);
a second control device (20) electrically coupled to the secondary side of the transformer (T) and configured to control the semiconductor switching element (M) using voltage signals present at the secondary side of the transformer (T); and
a diode (D) located between a terminal of the secondary side of the transformer (T) and the node (K).

2. The controller (100) according to claim 1, wherein the first control device (10) is further configured to sense an electrical current on the primary side of the transformer (T) and determine a switching state of the semiconductor switching element (M) using the sensed electrical current.

3. The controller (100) according to claim 2, wherein the first control device (10) is configured to detect a malfunction of the semiconductor switching element (M) if the determined switching state of the semiconductor switching element (M) deviates from the desired switching state signaled by the control pulses.

4. The controller (100) according to claim 1, wherein the control pulses each comprise a first time period (t1) and a second time period (t2), wherein the control pulses each have a predetermined first voltage level in the first time period (t1), and the control pulses have a voltage curve in the second time period (t2), with each signaling the desired switching state of the semiconductor switching element (M).

5. An electric inverter with:
an input terminal configured to be connected to a DC electric voltage source (1) at a first connection point and a second connection point; and
an inverter circuit (2) configured to convert a DC electric voltage supplied at the input terminal into an AC voltage and to supply it at an output terminal;
wherein a series circuit consisting of a Y-capacitor (Cy) and a semiconductor switching element (M) is arranged between a ground and the first connection point and between the ground and the second connection point, and
wherein a controller (100) according to claim 1 is provided for each Y-capacitor (Cy).

6. The electric inverter according to claim 5, wherein the controllers (100) are configured to close the semiconductor switching elements (M) in the series circuit consisting of the Y-capacitor (Cy) and semiconductor switching element (M) in a first operating mode, and
in a second operating mode, to open the semiconductor switching elements (M) in the series circuit consisting of the Y-capacitor (Cy) and semiconductor switching element (M).

7. An electric drive system for an electric vehicle, comprising:
an electric machine (3); and
an electric inverter according to claim 5 configured to control the electric machine (3).
